(19) United States
(12) Patent Application Publication
(10) Pub. No.: US 2015/0305211 A1
(43) Pub. Date: Oct. 22, 2015

(54) LIGHT WEIGHT CARBON FOAM AS ELECTROMAGNETIC INTERFERENCE (EMI) SHIELDING AND THERMAL INTERFACE MATERIAL

(71) Applicant: COUNCIL OF SCIENTIFIC & INDUSTRIAL RESEARCH, New Delhi (IN)

(72) Inventors: Sanjay Rangnath Dhakate, New Delhi (IN); Rajeev Kumar, New Delhi (IN); Rakesh Behari Mathur, New Delhi (IN); Parveen Saini, New Delhi (IN)

(21) Appl. No.: 14/646,323

(22) PCT Filed: Nov. 26, 2013
(86) PCT No.: PCT/IN2013/000714

§ 371 Date: May 20, 2015

(30) Foreign Application Priority Data
Nov. 26, 2012 (IN) 3615/DEL/2012

(51) Int. Cl. H05K 9/00; H05K 7/20; C23C 16/44; C09K 5/14; C23C 16/26

(52) U.S. Cl. CPC H05K 9/0081; C09K 5/14; C23C 16/26; C23C 16/44; H05K 7/2039

(57) ABSTRACT

The present invention deals with the development of light weight carbon foam from coal tar pitch as electromagnetic interference (EMI) shielding and thermal interface material for aerospace and aircraft systems protection. The carbon foam developed from mixing the MWCNTs in starting material in different weight fraction and also MWCNTs decorated on the carbon foam by chemical vapor deposition technique gives improved electromagnetic interference (EMI) shielding.

### FIELD OF THE INVENTION

The present invention relates to light weight carbon foam obtained from coal tar pitch and multi-walled carbon nanotubes for use as electromagnetic interference (EMI) shielding and thermal interface material for aerospace and aircraft systems protection. The present invention also provides for process for the preparation of light weight carbon foam.

### BACKGROUND OF THE INVENTION

Aerospace and aircraft power systems functioning significantly depend upon electronic systems, which require to be shielded against electromagnetic interference (EMI) and thermal interfacing due to the overheating of electronic systems. EMI may come in the form of lightening strikes, interference from radio emitters, nuclear electromagnetic pulses or even high power microwave threats. Traditional radiation shielding materials include boron, tungsten, Titanium, tantalum, silver, gold, or some combination of these materials etc. But these materials have disadvantages like high density, corrosion and difficulty in processing. A, light weight material is always preferred as radiation shielding materials in aerospace transportation vehicles and space structures. EMI shielding refers to the reflection and absorption of electromagnetic radiation by material. In case of reflection of the radiation by the shielding material, the shield material must have mobile charge carrier (electron or holes) which interact with the electromagnetic field in the radiation. As a result, the shield material tends to be electrically conducting. The electrical conductivity is not scientific criteria for shielding, as conduction requires connectivity in the conduction path. Metals are therefore the most common materials for EMI shielding and they function mainly by reflection due to the free electrons in them. The metal sheets are bulky, so metal coating made by electroplating, electroless plating and vacuum deposition are commonly used for shielding [Xingcun Colin Tong, Advanced Materials and Design for Electromagnetic Interference Shielding, CRC Press, 2008]. But it suffers from their poor wear or scratch resistance. However, absorption of shield material depends on the electric or magnetic dipoles, which interact with electromagnetic field of the radiation. Other than reflection and absorption, a mechanism of shielding is multiple reflections, which refer to the reflection at different surface or interfaces in the shield material. This mechanism requires presence of large surface area or interface area in the shield material. The losses due to multiple reflections can be neglected when the distance between the reflecting surface and interface is large as compared to skin depth. The electromagnetic radiations at high frequencies penetrate only near the surface region of the conducting material and this phenomenon known as skin effect. The conductive polymers [Shinagawa, Kumagai Y, Urabe K. J. Porous Material 1999; 6930:185-90] have become increasingly available but they are not common and tend to be poor in the process ability, mechanical properties, thermal stability and thermal conductivity. The continuous fiber polymer-matrix structural composites are capable of EMI shielding needed for aircrafts and aerospace electronic enclosures. But the fibers in these composites are typically carbon fibers and have low electrical conductivity, thereby requiring metal coating or to be intercalated to increase the conductivity. Despite the above, such materials have the disadvantage of thermal stability. The conductivity is prime requirement in the aerospace and aircraft system. Therefore, efforts have been paid to develop lightweight radiation shielding and thermal interface materials for aerospace transportation vehicles and space structure, which should have high surface area, electrically and thermally conductive at the same time thermally stable. A material in the form of foam possesses large surface area and high porosity.

Carbon foams (CF) are sponge-like high performance engineering materials in which carbon ligaments are interconnected to each other, and have recently attracted attention owing to their potential applications in various fields [Inagaki M. New Carbons: Control of Structure and Functions. Elsevier Sci. Ltd: Oxford ; 2000 and Rogers D, Plucinski J, Stansberry P, Stiller A, Zondlo J. In: Proceedings of the International SAMPE Symposium Exhibition, 45, New York, 2000; p. 293-305]. These have outstanding properties such as low density, large surface area with open cell wall structure, good thermal and mechanical stability coupled with tailorable thermal and electrical conductivity. This material is traditionally attractive for many aerospace and industrial applications including thermal insulation, porous electrodes, impact acoustic absorption, catalyst support, gas filtration and electro-magnetic interference shielding materials. In this invention main focus is given on the carbon foam as electromagnetic interference (EMI) shielding materials in different applications. EMI shielding refers to blocking of electromagnetic radiation so that the radiation essentially cannot pass through the shielding material.

Among the different material for both civil and military in aircraft and aerospace protection from electromagnetic radiation and thermal heating of electronic system, carbon materials have been considered as promising candidate since World War II. More recently, carbon foam (CF) has been prepared from thermosetting polymeric material by heat treatment in controlled atmosphere [Liu M, Gan L, Zhao F, Fan X, Xu H, Wu F, Carbon foams with high compressive strength derived foam using polyarylacetylene resin. Carbon 2007; 45: 3055-3057]. Later on, the carbon foams are synthesized from coal tar and petroleum pitches [Chen C, Kennel E, Stiller A, Stansberry P, Zondlo J. Carbon foam derived from various precursors. Carbon 2006; 44 :1535-1543.]. The foam derived from organic polymer and pitch gives low thermal conductivity, and these are predominantly used as a thermal insulation material [Cowlard F C, Lewis J C. Vitreous carbon—a new form of carbon. J Mater Sci. 1967; 2 (6):507-12 and Klett R D. High temperature insulating carbonaceous material. U.S. Pat. No. 3,914,392; 1975]. To make highly crystalline CF of high thermal conductivity, generally mesophase pitch is used as the starting material [Klett J, Hardy R, Romine E, Walls C, Burchell T. High thermal conductivity, mesophase-pitch-derived carbon foams: effect of precursor on structure and properties, Carbon 2000; 38: 953-973 and Klett J W, McMillan A D, Gallego N G, Burchell T D, Walls C A. Effect of heat treatment conditions on the thermal properties of mesophase pitch derived graphitic foams, Carbon 2004; 42: 1849-1852.] and it is prepared by high temperature and pressure foaming process. The final foam possesses cellular graphitic ligament microstructure, similarly to that of high thermal conductivity pitch based carbon fibers. The mesophase pitch based CF was developed for the first time at Wright-Patterson Air Force Base Materials Laboratory [Kearns K. Process for preparing pitch foams. U.S. Pat. No. 5,868,974; 1999]. Recently, number of researchers developed high thermal conductivity CF for different applications such as heat sink, light radiator, anode electrode material for lithium-ion batteries [Fang Z, CaO X, Li C, Zhang H, Zhang J, Zhang H. Investigation of carbon foams as microwave absorber: numerical prediction and experimental validation. Carbon 2006; 44(15):3348-78 and Fang Z, Li C, Sun J, Zhang H, Zhang J. The electromagnetic characteristics of carbon foams. Carbon 2007; 45(15):2873-9.]. Different methods are used for the development of CF, which are based on foaming of mesophase pitch followed by oxidation-stabilization, carbonization and graphitization [Gallego N C, Klett J W. Carbon foams for thermal management. Carbon 2003; 41(7):1461-6 and Wang M, Wang C Y, Li T Q, Hu Z J. Preparation of mesophase pitch-based carbon foams at low pressures. Carbon 2008; 46 (1):84-91]. Foaming has been achieved by either using blowing agent or pressure release process. Further, it is difficult to obtain carbon foam with large and uniform cells by the foaming methods. On the other hand, sacrificial template is a simple method by impregnating thermosetting resin [Inagaki M, Morishita T, Kuno A, Kito T, Hirano M, Suwa T, et al. Carbon foams prepared from polyimide using urethane foam template. Carbon 2004; 42(3):497-502] or petroleum pitch [Chen Y, Chen B, Shi X, Xu H, Hu Y, Yuan Y, et al. Preparation of pitch based carbon foam using polyurethane foam template. Carbon 2007; 45(10):2132-4] into a polyurethane foam template.

The application of carbon foam as EMI shielding material is reported by few authors. Yang et al [Yang J, Shen Z M, Hao Z B, Microwave characteristics of sandwitch composites with mesophase pitch carbon foams as core. Carbon 2004; 42:1882-85.] developed the carbon foam from mesophase pitch by foaming technique which are heated at temperature 400-800° C. and studied its microwave absorption characteristics. It is reported that carbon foam heat treated at 600 and 700° C. exhibit better microwave absorption (reflection loss 10 dB.). Fang et al [Fang Z, CaO X, Li C, Zhang H, Zhang J, Zhang H. Investigation of carbon foams as microwave absorber: numerical prediction and experimental validation, Carbon 2006; 44(15):3348-78] reported the numerical prediction and experimental validation of carbon foam as microwave absorber. The carbon foam was fabricated by traditional technique through the polymer foam replication method and foam was heat treated at 700,750 and 800° C., and characterized them microwave absorption. The reflection coefficient of 20 mm thick foam is in the order of 8-10 dB. Fang et al [Fang Z, Li C, Sun J, Zhang H, Zhang J. The electromagnetic characteristics of carbon foams. Carbon 2007; 45(15):2873-9]. studied electromagnetic characteristic of carbon foams having different pore size. The electromagnetic parameters of these carbon foams and their corresponding pulverized powders were measured by a resonant cavity perturbation technique at a frequency of 2.45 GHz. The carbon foam has dielectric loss several times larger than their corresponding pulverized powder. This suggests that for low temperature heat treated foam electro-magnetic shielding is dominated by absorption. Recently, Maglie et al [Maglie F, Micheli D, Laurenzi S, Marchetti M, Primiani V M. Electromagnetic shielding performance of carbon foams. Carbon 2012, 50, 1972-1980] studied the electromagnetic shielding of carbon foam (GRAFOAM FPA-20 and FRA-10) in the frequency band 1-4 GHz using the nested reverberation chamber method.

There are few patent on the synthesis of carbon foam as EMI shielding material, First patent is on the synthesis of high strength monolithic carbon foam from the polymeric material such as phenolic resin [Douglas J, Lewis Ervin C, Mercuri Robert A,. High strength Monilithic carbon foam (WO2007/121012 A2—US 2007063845)]. The compressive strength to density ratio 7000 psi/g/cc, this foam will be used for composite materials tooling, electromagnetic shielding and sound attenuation proposed.

Blacker et al [Blacker J M, Merriman D J. Carbon foam EMI Shield, (US20080078576 A1)] reported the carbon foam for EMI shielding. In their invention high conductive foams has EMI shielding effectiveness 40 dB in the frequency range 400 MHz-18 GHz. In certain embodiments, the carbon foam EMI shielding effectiveness was reported to be at least about 60 dB in the range of 400 to 8 GHz. Lucas et al [Lucas R. Carbonized shaped polymeric foam EMI shielding enclosure,(US2007/0277705A1)] reported the carbonized shaped polymer foam for partially EMI shielding enclose. The density of foam varies from 0.05 to 1.5 g/cc and compressive strength 50 psi to 12000 psi.

Matviya et al [Matviya T M, Rocks M K. Carbon bonded carbon foam EMI shielding enclosure (U.S. Pat. No. 7,960,656 B2/2011)] reported the carbon bonded carbon foam EMI shielding enclosure. In this invention, an enclosure made by connecting two section of electrically conducting carbon foam which are interconnected by electrically conducting carbon char. The enclosure is made from carbon foam partially shielding in the high frequency range 400 MHz to 18 GHz, in which bulk density of foam ranging from 0.05 to 1.5 g/cc. The compressive strength of carbonized foam is ranging from 50 psi to 12000 psi.

Blacker et al [Blacker, Jesse, M. and Plucinski Janusz, W. Electrically graded carbon foam (U.S. Pat. No. 7,867,608 B2/2011)] reported the development of electrically graded carbon foam materials that have increasing electrical resistivity through the thickness of the material and density ranging from about 0.05 g/cc to about 1.2 g/cc. These electrically graded carbon foam may be used as radar absorbers as well as electromagnetic interference shielding materials.

Sankaran et al [Sankaran S, Dasgupta S, Kandala R S, Narayana R B. Electrically conducting syntactic foam and a process for preparing the same, (US2011/0101284 A1)], reported the developed the electrically conducting syntactic foam and process for preparing the same. Design and development of carbon nanotube reinforced electrically conducting syntactic foam comprising resin matrix system. The prospective uses as lightweight multifunctional core materials in subsequent sandwich constructions designed as EMI shielding materials. The density of the syntactic foam varies from 0.3 to 0.9 g/cc, electrical resistivity ranges from 10 ohm.cm to 10¹⁰ ohm.cm and EMI shielding effectiveness in frequency range 100 KHz to 1 GHz is 40 dB.

Despite the above, there is felt a constant need to provide light weight carbon foam as electromagnetic interference (EMI) shielding and thermal interface material.

### OBJECTIVE OF THE INVENTION

Main objective of the present invention is to provide light weight carbon foam obtained from coal tar pitch and multi-walled carbon nanotubes (MWCNTs) for use as electromagnetic interference (EMI) shielding and thermal interface material for aerospace and aircraft systems protection.

Yet another objective of the present invention to provide a process for the preparation of light weight carbon foam from coal tar pitch and MWCNTs.

### BRIEF DESCRIPTION OF THE DRAWINGS

FIG. 1: The coal Tar Pitch based carbon foam heat treated at 2500° C.

FIG. 2: Coal tar pitch with MWCNT based carbon foam heat treated at 2500° C.

FIG. 3: MWCNTs decorated Coal tar pitch based carbon foam heat treated at 2500° C.

FIG. 4: EMI shielding effectiveness of MWCNTs decorated carbon foam.

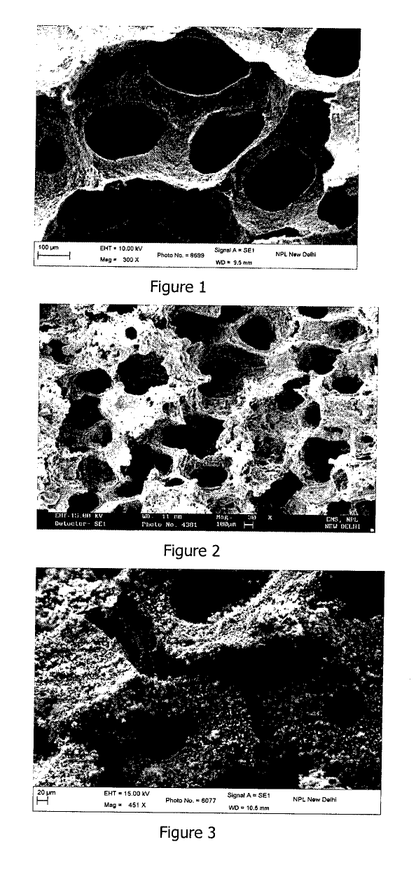

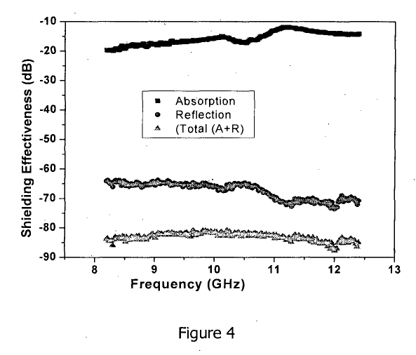

### SUMMARY OF THE INVENTION

Accordingly, present invention provides light weight carbon foam comprising carbon material obtained from coal tar pitch and multi walled carbon nanotubes (MWCNTs) characterized by EMI shielding effectiveness in the frequency region 8.2 to 12.4 GHz is in the range of 20-85 dB, bulk density in the range of 0.2 to 1.0 g/cc, porosity in the range of 50-80%, electrical conductivity in the range of 40-150 S/cm, thermal conductivity in the range of 20 to 80 W/m.K, compressive strength in the range of 2 to 10 MPa and thermal stability in air environment between temperature range 550 to 650° C.

In an embodiment of the present invention, said carbon foam is useful as electromagnetic interference (EMI) shielding and thermal interface material for aerospace and aircraft systems protection, electronic and medical instruments. The light weight carbon foam of the present invention can be prepared by incorporating different concentrations of multi walled carbon nanotubes (MWCNTs) in coal tar pitch during processing of foam to improve the EMI shielding of carbon foam. Alternatively, the different concentrations of MWCNTs can be grown on the carbon foam by chemical vapor deposition technique. Still more particularly, present invention relates to process for the preparation of light weight carbon foam.

In yet another embodiment, present invention provides a process for the preparation of light weight carbon foam comprising the steps of:
i. mixing 30 to 45 wt % coal tar pitch powder, 3 to 5wt % polymer with water and optionally with 0.25 to 5 wt. % dispersed MWCNTs to prepare the slurry followed by infiltration in the polyurethane foam template, stabilization, carbonization and graphitization to obtain carbon foam and MWCNT incorporated carbon foam respectively;
ii. and optionally, infiltrating the carbon foam as obtained in step (i) by the solution of ferrocene and toluene in the ratio ranging between 1:2 to 1:4 followed by growing MWCNTs by chemical vapor deposition technique to obtain MWCNT decorated carbon foam.

In another embodiment of the present invention, polymer used is selected from the group consisting of polyvinyl chloride, polyvinyl acetate and polyvinyl pyrrolidone.

In yet another embodiment of the present invention, stabilization is carried out in air or oxidizing atmosphere at temperature ranging between 200 to 400° C.

In yet another embodiment of the present invention, carbonation is carried out in inert atmosphere at temperature ranging from 900 to 1500° C.

In yet another embodiment of the present invention, graphitization is carried out in inert atmosphere at temperature ranging from 2000 to 3000° C.

In yet another embodiment of the present invention, coal tar pitch powder is optionally heat treated at temperature ranging between 300-500° C.

In yet another embodiment of the present invention, solvent dispersed MWCNTs optionally be mixed with coal tar pitch powder.

In yet another embodiment of the present invention, dispersion of MWCNTs is carried out in an organic solvent selected from group consisting of toluene, DMF, NMP, Acetone, ethanol either alone or combination thereof.

In yet another embodiment of the present invention, carbon foam as obtained in step (i) exhibit EMI shielding effectiveness in the frequency region 8.2 to 12.4 GHz is in the range of 24-45 dB, bulk density in the range of 0.45 to 0.51 g/cc, porosity in the range of 55 to 73%, electrical conductivity in the range of 54.9 -80 S/cm thermal conductivity in the range of 20 to 48 W/m.K, compressive strength in the range of 5.2 to 7.5 MPa and thermal stability in air environment between temperature range 550 to 650° C.

In yet another embodiment of the present invention, wherein MWCNT incorporated carbon foam as obtained in step (i) exhibit EMI shielding effectiveness in the frequency region 8.2 to 12.4 GHz is in the range of 33-72 dB, bulk density in the range of 0.54 to 0.59 g/cc, porosity in the range of 62-72%, electrical conductivity in the range of 110-138 S/cm thermal conductivity in the range of 52 to 70.2 W/m.K, compressive strength in the range of 6.2 to 7.6 MPa and thermal stability in air environment between temperature range 550 to 650° C.

In yet another embodiment of the present invention, MWCNT decorated carbon foam as obtained in step (ii) exhibit EMI shielding effectiveness in the frequency region 8.2 to 12.4 GHz is in the range of 45 to 85 dB, bulk density in the range of 0.51 to 0.57 g/cc, porosity in the range of 60-67%, electrical conductivity in the range of 50-150 S/cm thermal conductivity in the range of 45 to 80 W/m.K, compressive strength in the range of 6 to 9.3 MPa and thermal stability in air environment between temperature range 550 to 650° C.

### DETAILED DESCRIPTION OF THE INVENTION

The present invention relates to the development of light weight carbon foam as EMI shielding and thermal interface material for aerospace and aircraft systems protection.

The process for the preparation of these light weight carbon foam comprising the steps of:
i. heat treatment of coal tar pitch at temperature ranging between 300-500° C. and preparation of foam from heat treated pitch by sacrificial template method in which the polyurethane foam infiltrated by the slurry of pitch;
ii. stabilization of foam, carbonization and graphitization to get carbon foam.

The stabilization of foam is carried out at temperature in the range of 200-400° C. in oxidizing atmosphere.

The carbonization and graphitization of stabilized foam is carried out at temperature in the range of 900-3000° C. in inert atmosphere.

Multiwall carbon nanotubes (MWCNTs) in different weight content mixed with heat treated coal tar pitch and carbon foam developed there from.

The MWCNTs dispersed in suitable solvent (toluene, DMF, NMP, Acetone, ethanol combinations thereof) using ultra-sonication and magnetic stirring to get individual nanotubes separated. The dispersed MWCNTs mixed in heat treated coal tar pitch in different weight fraction (0.25 to 5 wt %) and ball milled to get uniformly mixed MWCNTs in pitch and carbon foam developed there from. Commercial MWCNTs are used for the same.

MWCNTs in different weight fraction is grown on the carbon foam by chemical vapor deposition technique.

Light weight carbon foam which has bulk density in the range of 0.4 to 0.7 g/cc, corrosion resistant, high specific thermal connectivity and thermal stability as high as 600° C. in the oxidizing atmosphere.

It is simple process in which MWCNTs can easily incorporate in the carbon foam which can align in the ligament which contributes in increases in the conducting continuous network.

The MWCNTs (0.5 to 1%) can be easily decorated on the carbon foam and by controlling the processing parameter by chemical vapor deposition technique which can improve the surface conductivity of carbon foam and EMI shielding will dominated by multiple reflection due to increases in surface area.

These light weight MWCNTs incorporated carbon foam or MWCNTs decorated carbon foam as electromagnetic interference shielding material is used as in the frequency range 8.2 to 12.4 GHz (X-band) with EMI shielding effectiveness up to 85 dB.

It will be used as thermal interface material for aerospace and aircraft systems protection, shielding of electronic equipment's, medical instruments etc.

Present invention provides carbon foam developed from coal tar pitch, mixture of coal tar pitch and MWCNTs (0.5 to 2%). Carbon nanotubes were grown in the pores, ligaments of foam (MWCNT content 0.25 to 1.5%). In the carbon foam, ligaments are interconnected to each other in 3D structure. MWCNTs are aligned in the ligaments and grown on the ligaments. This is responsible in the overall enhancement of electrical and thermal conductivity of carbon foam. However, bulk density is not influenced much on the addition of MWCNTs. The density of carbon foam varied from 0.4 to 0.65 g/cc. The compressive strength is increased from 4 MPa to 10 MPa with the use of MWCNTs. The EMI shielding effectiveness in the X-band Frequency range (8.2-12.4 GHz) of as such carbon foam is in the range of 24 to 45 dB. On addition of MWCNTs during the processing of carbon foam in the pitch, EMI shielding effectiveness is improved from 45 to 72 dB.

However, on the growth of MWCNTs on the carbon foam, EMI shielding effectiveness improved from 45 to 85 dB. All the carbon foams are thermally stable up to 600° C. in air atmosphere.

### EXAMPLES

The following examples are given by way of illustration and therefore should not be construed to limit the scope of the present invention.

### Example 1

The coal tar pitch having 0.5% quinoline insoluble content of desired quantity was grounded in to fine power by ball mill. The grounded fine powder of coal tar pitch (35 wt. %) mixed with water and 3 wt % of polyvinyl chloride to prepare the infiltreable slurry which is infiltrated in the polyurethane foam template. The coal tar pitch slurry impregnated template foam was stabilized in air at 300° C. temperature. The stabilized foam was carbonized in inert atmosphere at 1000° C. The resultant carbon foam possesses bulk density 0.45 g/cc and porosity 55%, Compressive strength_{—}7.5 Mpa, electrical conductivity 54.9 S/cm, thermal conductivity 20 W/m.K and EMI shielding effectiveness 24 dB. The reflection and absorption shielding effectiveness is 12 dB and 12 dB respectively.

### Example 2

The above process of foam development was repeated (Example 1). The foam was graphitized in inert atmosphere at 2500° C. temperature. The resultant carbon foam possesses bulk density 0.51 g/cc and porosity 73%, electrical conductivity 82 S/cm, thermal conductivity 48 W/m.K and EMI shielding effectiveness 45 dB. The EMI shielding effectiveness was dominated by reflection shielding effectiveness. The compressive strength of carbon foam was 5.2 MPa.

### Example 3

The coal tar pitch heat treated at 400° C. was used for the development of carbon foam. The commercially available MWCNTs were used for mixing with the heat treated coal tar pitch. The MWCNTs was dispersed in acetone. The dispersed MWCNTs was mixed in the coal tar pitch by ball milling process. The 0.5 wt. % MWCNTs was mixed with the coal tar pitch. Thereafter carbon foam was developed as per procedure given in the example 1 and 2. The resultant carbon foam possesses bulk density 0.54 g/cc and porosity 72%, electrical conductivity 126 S/cm, thermal conductivity 59 W/m.K, compressive strength 6.4 MPa and EMI shielding effectiveness 60 dB.

### Example 4

The above process of foam formation from the mixture of MWCNTs and heat treated coal tar pitch was repeated (example 3). In this example the MWCNTs content was 1.0 wt. % mixed with the coal tar pitch. Thereafter carbon foam was developed as per procedure given in the example 3. The resultant carbon foam possesses bulk density 0.57 g/cc and porosity 68%, electrical conductivity 138 S/cm, thermal conductivity 70.2 W/m.K, compressive strength 7.6 MPa and EMI shielding effectiveness 72 dB. The stability of carbon foam air atmosphere was 600° C., there was no weight loss up to 600° C.

### Example 5

The above process of foam formation from the mixture of MWCNTs and heat treated coal tar pitch was repeated (example 3). In this example the MWCNTs content was 2.0 wt. % mixed with the coal tar pitch. Thereafter carbon foam was developed as per procedure given in the example 3. The resultant carbon foam possesses bulk density 0.59 g/cc and porosity 62%, electrical conductivity 110 S/cm, thermal conductivity 52 W/m.K, compressive strength 6.2 MPa and EMI shielding effectiveness 33 dB. The stability of carbon foam air atmosphere was 600° C., there was no weight loss up to 600° C.

### Example 6

In this case the MWCNTs were grown on the carbon foam developed as per example 1 and 2. The MWCNTs was grown by chemical vapor deposition technique. Initially, carbon foam heat treated at 2500° C. was infiltrated by the solution of ferrocene and toluene in 1:3 ratio. The toluene was a source of hydrocarbon and ferrocene as organomettalic catalyst. The impregnated carbon foam was kept inside a quartz reactor of the CVD furnace and temperature of a reaction zone was maintained at 750° C. Once the desired temperature was reached, the solution of ferrocene and toluene was injected in the reactor@20 ml/hr. The argon gas was also fed along with solution of ferrocene and toluene, as a carrier gas and its flow rate 2 lit/min was adjusted so that the maximum amount of precursor must have been consumed inside the desired zone. The other processing parameter was controlled to grow the requisite amount of MWCNTs on carbon foam and carbon foam possesses the 0.5 wt. % of MWCNTs. The resultant carbon foam possesses bulk density 0.51 g/cc and porosity 67%, electrical conductivity 150 S/cm, thermal conductivity 80 W/m.K, compressive strength 9.3 MPa and EMI shielding effectiveness 85dB. The stability of carbon foam in air atmosphere was 600° C., there was no weight loss up to 600° C.

### Example 7

In this case the MWCNTs were grown on the carbon foam developed as per example 1, 2 and 6. The MWCNTs was grown by chemical vapor deposition technique. The carbon foam heat treated at 2500° C. was infiltrated by the solution of toluene and ferrocene. The toluene was a source of hydrocarbon and ferrocene as organomettalic catalyst. The processing parameter was controlled to grow the requisite amount of MWCNTs on carbon foam and carbon foam possesses the 1.0 wt. % of MWCNTs. The resultant carbon foam possesses bulk density 0.53 g/cc and porosity 65%, electrical conductivity 130 S/cm, thermal conductivity 68.5 W/m.K , compressive strength 7.0 MPa and EMI shielding effectiveness 60 dB. The stability of carbon foam in air atmosphere was 600° C., there was no weight loss up to 600° C.

### Example 8

In another example, MWCNTs were grown on the carbon foam developed as per example 1,2 and 6. The MWCNTs was grown by chemical vapor deposition technique. The carbon foam heat treated at 2500° C. was infiltrated by the solution of toluene and ferrocene. The toluene was a source of hydrocarbon and ferrocene as organomettalic catalyst. The processing parameter was controlled to grow the requisite amount of MWCNTs on carbon foam and carbon foam possesses the 2.0 wt. % of MWCNTs. The resultant carbon foam possesses bulk density 0.57 g/cc and porosity 60%, electrical conductivity 80 S/cm, thermal conductivity 45 W/m.K, compressive strength 6.0 MPa and EMI shielding effectiveness 45 dB. The stability of carbon foam in air atmosphere was 600° C., there was no weight loss up to 600° C.

TABLE 1
Characteristics of the different type of Carbon Foam

| | EMI | | | | | | |
|---|---|---|---|---|---|---|---|
| | shielding | Thermal | | Electrical | Thermal | Compres- | |
| | effective- | stability in | | conduc- | Conduc- | sive | Bulk |
| Type of Foam | ness | air atm. | Porosity | tivity | tivity | strength | density |
| as such carbon | 24 dB | up to 600° C. | 55% | 54.9 | 20 | 7.5 MPa | 0.45 g/cc |
| foam | | | | S/cm | W/m · K | | |
| Graphitized Foam | 45 dB | up to 600° C. | 73% | 82 | 48 | 5.2 MPa | 0.51 g/cc |
| (at 2500° C.) | | | | S/cm | W/m · K | | |
| 0.5 wt. % MWCNTs | 60 dB | up to 600° C. | 72% | 126 | 59.0 | 6.4 MPa | 0.54 g/cc |
| incorporated | | | | S/cm | W/m · K | | |
| carbon foam | | | | | | | |
| 1.0 wt. % MWCNTs | 72 dB | up to 600° C. | 68% | 138 | 70.2 | 7.6 MPa | 0.57 g/cc |
| incorporated | | | | S/cm | W/m · K | | |
| carbon foam | | | | | | | |
| 2.0 wt. % MWCNTs | 33 dB | up to 600° C. | 62% | 110 | 52 | 6.2 MPa | 0.59 g/cc |
| incorporated | | | | S/cm | W/m · K | | |
| carbon foam | | | | | | | |
| 0.5 wt. % MWCNTs | 85 dB | up to 600° C. | 67% | 150 | 80 | 9.3 MPa | 0.51 g/cc |
| decorated carbon | | | | S/cm | W/m · K | | |
| foam | | | | | | | |
| 1.0 wt. % MWCNTs | 60 dB | up to 600° C. | 65% | 130 | 68.5 | 7.0 MPa | 0.53 g/cc |
| decorated carbon | | | | S/cm | W/m · K | | |
| foam | | | | | | | |
| 2.0 wt % MWCNTs | 45 dB | up to 600° C. | 60% | 80 | 45 | 6.0 MPa | 0.57 g/cc |
| decorated carbon | | | | S/cm | W/m · K | | |
| foam | | | | | | | |

### ADVANTAGE OF THE INVENTION

1. Light weight carbon foam which has bulk density in the range of 0.4 to 0.7 g/cc, corrosion resistant, high specific thermal connectivity and thermal stability as high as 600° C. in the oxidizing atmosphere.

2. It is simple process in which MWCNTs can easily incorporate in the carbon foam which can align in the ligament which contributes in increases in the conducting continuous network.

3. The MWCNTs can be easily decorated on the carbon foam surface and by controlling the processing parameter by chemical vapor deposition technique.

4. The light weight carbon foam incorporated or decorated by MWCNTs can be used as electromagnetic shielding material for thermal interface material for aerospace and aircraft systems protection, shielding of electronic equipment's, medical instruments etc.

We claim:

1. Light weight carbon foam comprising carbon material obtained from coal tar pitch and multi walled carbon nanotubes (MWCNTs) characterized by EMI shielding effectiveness in the frequency region 8.2 to 12.4 GHz is in the range of 20-85 dB, bulk density in the range of 0.2 to1.0 g/cc, porosity in the range of 50-80%, electrical conductivity in the range of 40-150 S/cm thermal conductivity in the range of 20 to 80 W/m.K, compressive strength in the range of 2 to 10 MPa and thermal stability in air environment between temperature range 550 to 650° C.

2. The carbon foam as claimed in claim 1, wherein said carbon foam is useful as electromagnetic interference (EMI) shielding and thermal interface material for aerospace and aircraft systems protection, electronic and medical instruments.

3. A process for the preparation of light weight carbon foam as claimed in claim 1 and the said process comprising the steps of:
i. mixing 30 to 45 wt % coal tar pitch powder, 3 to 5wt % polymer with water and optionally with 0.25 to 5 wt. % dispersed MWCNTs to prepare the slurry followed by infiltration in the polyurethane foam template, stabilization, carbonization and graphitization to obtain carbon foam and MWCNT incorporated carbon foam respectively; and
ii. optionally, infiltrating the carbon foam as obtained in step (i) by the solution of ferrocene and toluene in the ratio ranging between 1:2 to 1:4 followed by growing MWCNTs by chemical vapor deposition technique to obtain MWCNT decorated carbon foam.

4. The process as claimed in claim 3, wherein polymer used is selected from the group consisting of polyvinyl chloride, polyvinyl acetate and polyvinyl pyrrolidone.

5. The process as claimed in claim 3, wherein stabilization is carried out in air or oxidizing atmosphere at temperature ranging between 200 to 400° C.

6. The process as claimed in claim 3, wherein carbonation is carried out in inert atmosphere at temperature ranging from 900 to 1500° C.

7. The process as claimed in claim 3, wherein graphitization is carried out in inert atmosphere at temperature ranging from 2000 to 3000° C.

8. The process as claimed in claim 3, wherein coal tar pitch powder is optionally heat treated at temperature ranging between 300-500° C.

9. The process as claimed in claim 3, wherein solvent dispersed MWCNTs optionally be mixed with coal tar pitch powder.

10. The process as claimed in claim 9, wherein dispersion of MWCNTs is carried out in an organic solvent selected from group consisting of toluene, DMF, NMP, Acetone, ethanol either alone or combination thereof.

11. The process as claimed in claim 3, wherein carbon foam as obtained in step (i) exhibit EMI shielding effectiveness in the frequency region 8.2 to 12.4 GHz is in the range of 24-45 dB, bulk density in the range of 0.45 to 0.51 g/cc, porosity in the range of 55 to 73%, electrical conductivity in the range of 54.9 -80 S/cm thermal conductivity in the range of 20 to 48 W/m.K, compressive strength in the range of 5.2 to 7.5 MPa and thermal stability in air environment between temperature range 550 to 650° C.

12. The process as claimed in claim 3, wherein MWCNT incorporated carbon foam as obtained in step (i) exhibit EMI shielding effectiveness in the frequency region 8.2 to 12.4 GHz is in the range of 33-72 dB, bulk density in the range of 0.54 to 0.59 g/cc, porosity in the range of 62-72%, electrical conductivity in the range of 110-138 S/cm thermal conductivity in the range of 52 to 70.2 W/m.K, compressive strength in the range of 6.2 to 7.6 MPa and thermal stability in air environment between temperature range 550 to 650° C.

13. The process as claimed in claim 3, wherein MWCNT decorated carbon foam as obtained in step (ii) exhibit EMI shielding effectiveness in the frequency region 8.2 to 12.4 GHz is in the range of 45 to 85 dB, bulk density in the range of 0.51 to 0.57 g/cc, porosity in the range of 60-67%, electrical conductivity in the range of 50-150 S/cm thermal conductivity in the range of 45 to 80 W/m.K, compressive strength in the range of 6 to 9.3 MPa and thermal stability in air environment between temperature range 550 to 650° C.
